(19) United States
(12) Patent Application Publication
(10) Pub. No.: US 2025/0159818 A1
(43) Pub. Date: May 15, 2025

(54) DISPLAY DEVICE

(71) Applicant: Lenovo (Singapore) Pte. Ltd., Singapore (SG)

(72) Inventors: Moriyuki Tsuchihashi, Kanagawa (JP); Kazuo Fujii, Kanagawa (JP)

(73) Assignee: Lenovo (Singapore) Pte. Ltd., Singapore (SG)

(21) Appl. No.: 18/823,157

(22) Filed: Sep. 3, 2024

(30) Foreign Application Priority Data
Nov. 15, 2023 (JP) 2023-194720

(51) Int. Cl. H05K 5/02

(52) U.S. Cl. CPC H05K 5/0217

(57) ABSTRACT

A display device includes: an OLED; a winder that winds the OLED from one end of the OLED; a cover that keeps a winding space for the OLED between the winder and the cover; a constant force spring that applies a winding force of the OLED to the winder; a motor configured to give at least one of winding and unwinding forces of the OLED to the winder; a drag mechanism configured to transmit rotation between the motor and the winder via a friction element; and a weight at the other end of the OLED to apply a pull-out force that counterbalances the winding force by the constant force spring.

### CROSS-REFERENCE TO RELATED APPLICATIONS

This application claims priority to Japanese Patent Application No. 2023-194720 filed on Nov. 15, 2023, the contents of which are hereby incorporated herein by reference in their entirety.

### TECHNICAL FIELD

The present invention relates to a rollable display device.

### BACKGROUND

Japanese Unexamined Patent Application Publication No. 2021-140162 discloses a rollable display device that can be wound up. This display device has a display unit that is wound and stored inside a stationary housing, and the display unit moves up and down by the action of a motor using a link mechanism.

A rollable display device can be stored with a small area and volume, but the display device in Japanese Unexamined Patent Application Publication No. 2021-140162 has a link mechanism and other components, making it large overall. Such a display device is easy to use for users if it can be wound or unwound manually, rather than just electrically.

### SUMMARY

One or more embodiments of the present invention provide a small, rollable display device enabling its electrical and manual operations.

A display device according to one or more embodiments of the present invention includes: an OLED; a winder that winds the OLED from one end of the OLED; a cover that keeps a winding space for the OLED between the winder and the cover; a constant force spring that applies a winding force of the OLED to the winder; a motor configured to give at least one of winding and unwinding forces of the OLED to the winder; a drag mechanism configured to transmit rotation between the motor and the winder via a friction element; and a weight at the other end of the OLED to apply a pull-out force that counterbalances the winding force by the constant force spring.

According to one or more embodiments of the present invention, the display device has a simple configuration of transmitting rotation between the motor and the winder via a friction element, and includes the constant force spring and the weight that are balanced, so that a small motor is sufficient. This makes it possible to reduce the overall size of the device. In addition, slippage occurs at the friction elements, making it possible to both electrical and manual operations.

### BRIEF DESCRIPTION OF THE DRAWINGS

FIG. 1 schematically illustrates a display device according to one or more embodiments of the present invention, and its external devices.

FIG. 2 is a schematic cross-sectional side view of the display device.

FIG. 3 is a schematic cross-sectional front view of the display device according to one or more embodiments.

FIG. 4 is a schematic perspective view of a constant force spring.

FIG. 5 is a schematic exploded perspective view of a drag mechanism.

FIG. 6 is a schematic cross-sectional front view of a display device according to one or more embodiments.

FIGS. 7A-7D illustrate examples of the use of the display device, with FIG. 7A illustrating the storage state, FIG. 7B illustrating the ready for use state, FIG. 7C illustrating the use state, and FIG. 7D illustrating another use state.

### DETAILED DESCRIPTION

The following describes a display device according to embodiments of the present invention in details, with reference to the drawings. The present invention is not limited to the following embodiments.

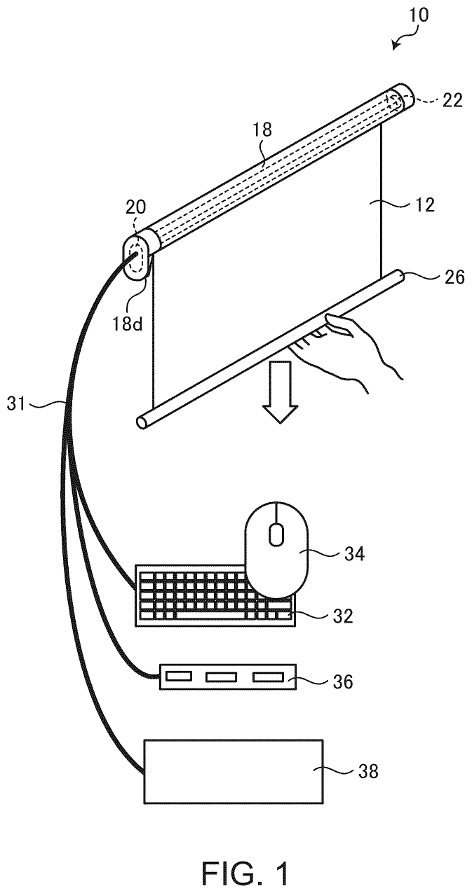

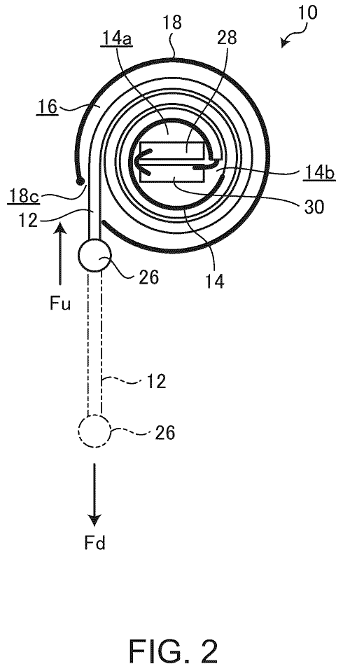

FIG. 1 schematically illustrates a display device 10 according to one or more embodiments of the present invention, and its external devices. FIG. 2 is a schematic cross-sectional side view of the display device 10.

The display device 10 includes a display that is an organic light emitting display (OLED) 12. The OLED 12 has features of its thinness and lightness in weight, low power consumption, and excellent contrast and responsiveness. The OLED 12 is flexible, meaning it is capable of being wound up, but its bending elasticity is relatively strong to have the property of returning to a flat shape in the absence of an external force. The following describes the display device 10: a display device 10A according to one or more embodiments; and a display device 10B according to one or more embodiments in this order. The OLED 12 in these embodiments may have the dimensions of about 20 inches or 30 inches, for example.

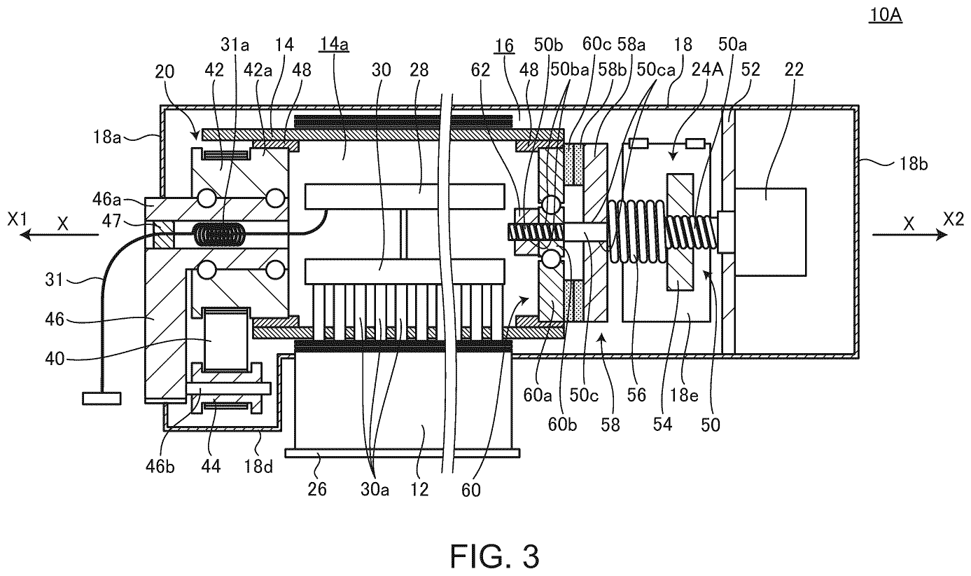

FIG. 3 is a schematic cross-sectional front view of the display device 10 according to one or more embodiments. The display device 10A includes an OLED 12, a cylinder (winder) 14, a cover 18, a constant force spring 20, a motor 22, a drag mechanism 24A, a pull-out bar (weight) 26, a controller 28, and a display controller 30. The cylinder 14 is tubular and has a surface, around which the OLED 12 is wound from one end 12a. In the description of the display device 10A, the extension direction of the cylinder 14 is defined as X direction. The cylinder 14 is tubular, and X direction corresponds to the axis direction of the tubular cylinder 14. The constant force spring 20, and the motor 22 and drag mechanism 24A are located on the opposite sides of the cylinder 14, and the direction toward the constant force spring 20 is defined as X1 direction and the direction toward the motor 22 and drag mechanism 24A is defined as X2 direction.

The cylinder 14 has a hollow 14a, in which the controller 28 and display controller 30 are placed. The controller 28 and the display controller 30 are elongated and extend in the X direction. The controller 28 and display controller 30 are connected by a control line.

The controller 28 corresponds to a motherboard in a typical personal computer. The controller 28 performs overall control of the display device 10A, and connects to external devices via an interface cable 31. The interface cable 31 has a spiral portion 31a so that the rotation of the cylinder 14 is not transmitted to the outside. The controller 28 also controls the motor 22. The controller 28 rotates the motor 22 in the normal and reverse directions in accordance with a predetermined operation signal, thereby applying a force for winding and unwinding the OLED 12 to the cylinder 14. For some specifications, the controller 28 may give at least one of the winding and unwinding forces of the OLED 12. For power transmission between the controller 28 and the motor 22, the power line may have a spiral portion, or a slip ring may be used.

The external devices include a keyboard 32, a mouse 34, a communication port 36, and an external battery 38. These external devices are connected as needed and may be disconnected when not needed. The controller 28 may be located outside the display device 10A. The battery may be located inside the display device 10A.

The display controller 30 controls the display of the OLED 12 and is a timing controller, for example. The cylinder 14 has a slit 14b (see FIG. 2), and one end 12a of the OLED 12 is connected to the display controller 30 via a plurality of display control lines 30a through this slit 14b. From the viewpoint of horizontal display timing, the display controller 30 is desirably placed in the horizontal direction near the one end 12a of the OLED 12, thus its layout in the X direction may be within the hollow 14a.

The cover 18 is a tubular housing that covers the entire display device 10A, and has both ends closed by lids 18a and 18b. The lids 18a and 18b may be provided with a power switch, a switch for adjusting the brightness of the OLED 12, a switch for raising and lowering the OLED 12, and others. The cover 18 has a bulge 18d near the X1 end to accommodate the constant force spring 20. The cover 18 has a diameter somewhat larger than that of the cylinder 14 so as to have a winding space 16 for the OLED 12 between itself and the cylinder 14. The diameter of the cover 18 is about 30 mm in one or more embodiments.

The cover 18 has a slit 18c (see FIG. 2), through which the OLED 12 is unwound. The other end 12b of the OLED 12 is outside the slit 18c. The other end 12 is provided with the pull-out bar 26 along its entire length. The pull-out bar 26 lets the user grip it when unwinding the OLED 12, and is made of stainless steel, for example, and has a diameter that makes it easy to grip. When the display device 10A is in a horizontal position, the pull-out bar 26 exerts a force Fd (see FIG. 2) that unwinds the OLED 12 downward due to its own weight.

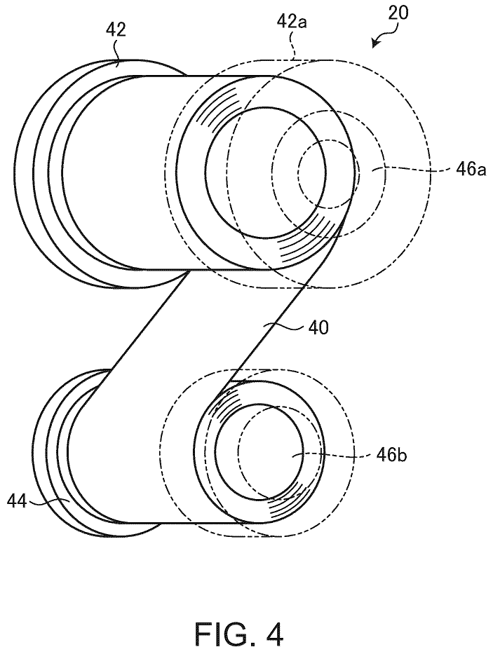

FIG. 4 is a schematic perspective view of the constant force spring 20. In FIG. 4, a part of the spring is illustrated by the dash-dot-dot imaginary lines. Referring to FIGS. 3 and 4, the following describes the constant force spring 20. The constant force spring 20 is placed at the X1 end of the cover 18. The constant force spring 20 includes an elastic band 40, a first pulley 42, and a second pulley 44. The first and second pulleys 42 and 44 are supported by first and second shafts 46a and 46b of a spring support 46. The spring support 46 is fixed to the lid 18a. A sensor for detecting a rotation angle may be placed between the first pulley 42 and the first shaft 46a so that the controller 28 understands the amount of the OLED 12 that has been unwound.

A cylinder support 42a, which is located at the X2 end of the first pulley 42, is appropriately wide in the X direction, and is fixed to the inner wall of the cylinder 14 via a rubber ring 48. The first pulley 42 has a larger diameter than the second pulley 44. The first pulley 42 has a width in the X direction larger than that of the second pulley 44, and has a bearing structure between itself and the first shaft 46a. For instance, this bearing structure is of a double-row type, which allows the cylinder 14 to be stably supported for smooth rotation. The first shaft 46a has a hollow structure, through which the interface cable 31 passes. The interface cable 31 is secured in the hollow of the first shaft 46a with a grommet 47. The first pulley 42 is coaxial with the cover 18, and the second pulley 44 is in the bulge 18d. Although the constant force spring 20 is partially located in the bulge 18d, most of it fits inside the tube of the cover 18 and is small enough and lightweight enough.

The elastic band 40 is a metal spring member having bending elasticity such that it inherently spirals, which may be a spiral spring. The elastic band 40 hardly stretches in the pulling direction. The first pulley 42 is located at the X1 end of the cylinder 14, and the elastic band 40 is wound around the first pulley 42 in the opposite direction to the direction in which the elastic band 40 inherently spirals. The second pulley 44 winds the elastic band 40 that is unwound from the first pulley 42 in the inherent spiral direction.

Such a constant force spring 20 always exerts a constant elastic force regardless of the amount of unwinding of the elastic band 40, thereby applying a rotational force to the first pulley 42. This rotational force gives a force Fu (see FIG. 2) that winds the OLED 12 around the cylinder 14. The winding force Fu and the unwinding force Fd as stated above are set to be equal. The forces Fu and Fd, which depend on the size of the OLED 12, are about 800 gf, for example.

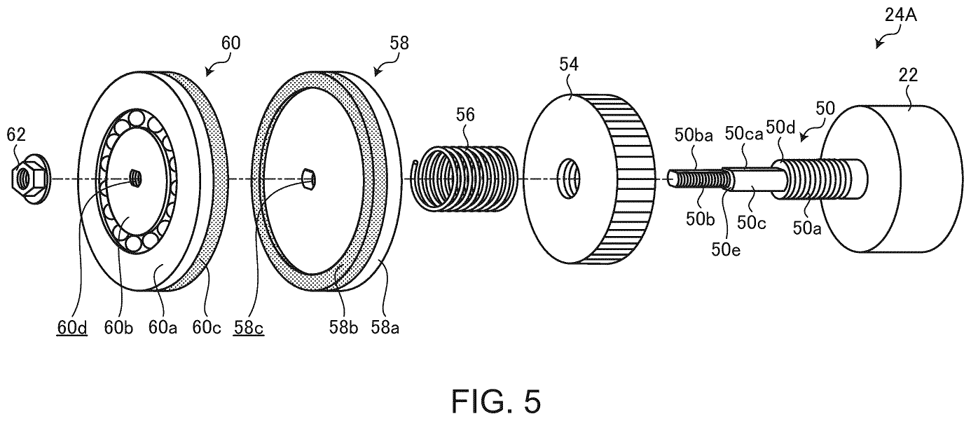

FIG. 5 is a schematic exploded perspective view of the drag mechanism 24A. Referring to FIGS. 3 and 5, the following describes the motor 22 and the drag mechanism 24A. For instance, the motor 22 is a DC motor with a built-in decelerator, and applies a force for winding and unwinding the OLED 12 to the cylinder 14 via the drag mechanism 24A. As described above, the motor 22 is located at the X2 end of the cover 18. The motor 22 and its rotating shaft 50 are supported on the inner wall of the cover 18 via a bracket 52. A bearing may be placed between the rotating shaft 50 and the bracket 52.

The drag mechanism 24A is placed between the motor 22 and the cylinder 14, and includes an adjustment nut 54, a coil spring 56, a friction disc 58, a bearing 60, and a fixing nut 62, and further includes the rotating shaft 50 of the motor 22. The motor 22 and the drag mechanism 24A are housed inside the cover 18 and are small and lightweight.

The rotating shaft 50 has: a base threaded portion 50a with a relatively large diameter closer to the X2 end; a tip threaded portion 50b with a relatively small diameter closer to the X1 end; and an intermediate portion 50c with a medium diameter and located between the base threaded portion 50a and the tip threaded portion 50b. The rotating shaft 50 has a step 50d at the boundary between the base threaded portion 50a and the intermediate portion 50c, and has a step 50e at the boundary between the intermediate portion 50c and the tip threaded portion 50b. The tip threaded portion 50b has a two-sided D-cut shape with two parallel flat surfaces 50ba. The intermediate portion 50c has a two-sided D-cut shape with two parallel flat surfaces 50ca.

The bearing 60 has an outer ring 60a, an inner ring 60b, and a friction plate 60c. The inner ring 60b has a two-sided D-cut hole 60d in the center, into which the tip threaded portion 50b is fitted so as to be non-rotatable relative to the inner ring 60b. Having the tip threaded portion 50b fitted in the hole 60d, the inner ring 60b has an X2 side face abutting against the step 50e, and has an X1 side face fixed to the rotating shaft 50 with a fixing nut 62 that screws onto the tip threaded portion 50b.

The outer ring 60a has the same diameter as the cylinder support 42a described above and is fixed to the inner wall of the cylinder 14 via a rubber ring 48. The friction plate 60c is annular with an appropriately large radial width, and is placed along the periphery of the X2 side face of the outer ring 60a. The friction plate 60c may be omitted for some design conditions.

The friction disc 58 has a circular plate 58a and a friction plate 58b. The circular plate 58a is made of a metal material and has a two-sided D-cut hole 58c in the center, into which the intermediate portion 50c fits non-rotatably. The circular plate 58a has this hole 58c, into which the intermediate portion 50c fits, whereby the circular plate 58a is non-rotatable relative to the rotating shaft 50 but movable in the axial direction.

The circular plate 58a has the same diameter as the outer ring 60a. The friction plate 58b is the same as the friction plate 60c, and is placed along the periphery of the X1 side face of the circular plate 58a. In other words, the friction plates 58b and 60c face each other. The friction plates (friction elements) 58b and 60c may be made of a material that generates a relatively small frictional force and is less susceptible to deterioration over time, such as polyacetal, cork, or felt. In FIGS. 3 and 5, the friction plates 58b and 60c are illustrated in dotted pattern. The friction plates 58b and 60c are of the dry type, and are therefore stable without being affected by oil film.

The adjustment nut 54 is screwed onto the base threaded portion 50a, and its screw position is adjustable manually or with a tool after opening the door 18e of the cover 18. Two adjustment nuts 54 may be provided to fix the position using a double nut system. The coil spring 56 is placed between the adjustment nut 54 and the friction disc 58, and the amount of compression is adjusted by the adjustment nut 54. In other words, the friction disc 58 including the friction plate 58b is elastically pressed against the outer ring 60a and friction plate 60c, which are the friction target, by the coil spring 56 under the force exerted by the base threaded portion 50a and adjustment nut 54. The amount of compression of the coil spring 56 adjusts the surface pressure between the friction plates 58b and 60c to adjust the friction force generated between them. The frictional force generated between the friction plates 58b and 60c is small, and in one or more embodiments, is about 100 to 200 gf that is converted into the force for unwinding and winding the OLED 12.

The display device 10A configured in this manner has the OLED 12, constant force spring 20, motor 22, and drag mechanism 24A housed inside the tubular cover 18, and is small, lightweight, inexpensive, and highly portable. The display device 10A does not require a link mechanism as in Japanese Unexamined Patent Application Publication No. 2021-140162, has a simple configuration and is lightweight, and does not require a large power source to drive the link mechanism. Thus, the motor 22 can be small.

Although the OLED 12 has a property to return to a flat shape, it is constantly biased by the constant force spring 20, so that it is maintained in an appropriate wound state around the cylinder 14 and does not expand radially outward within the space 16 to come into contact with the inner wall of the cover 18. Therefore, it does not slide against the cover 18 and is not damaged or subjected to unnecessary frictional forces.

In manual operation of the display device 10A, the user is allowed to unwind the OLED 12 by grasping the pull-out bar 26 and pulling it downward. At this time, the cylinder 14, the first pulley 42 and the outer ring 60a rotate together, while the rotating shaft 50, the friction disc 58 and the inner ring 60b do not rotate. Although the friction disc 58 receives a rotational force from the friction plate 58b, it stops due to the action of the built-in decelerator of the motor 22. Assuming a force of 10 gf is required to pull down the pull-out bar 26 and a reduction ratio of 1:120 is used, then the force becomes 10×120=1200 gf. This means that even if the frictional force that the friction disc 58 receives is considerable, the rotating shaft 50 will not rotate and will remain stopped. Practically, the rotating shaft 50 does not rotate by hand, even with pliers or other tools. Although slippage occurs between the friction plate 58b and the friction plate 60c, the frictional force between them is set to be sufficiently small, so that the unwinding of the OLED 12 is hardly affected.

The winding force Fu and the unwinding force Fd are basically set equal, meaning that the user is able to pull out the OLED 12 with a very small force regardless of the amount unwound from the cover 18. Furthermore, it also provides a free stop function that allows the device to be stopped at any position.

It is desirable for the forces Fu and Fd to be perfectly equal, but it may be difficult to achieve a perfect balance due to factors such as practical tolerances. However, even if there is a slight difference between the forces, the frictional force of about 100 to 200 gf between the friction plates 58b and 60c provides a light braking action as described above, making free stopping possible. When storing the OLED 12 inside the cover 18, the user gently pushes up the pull-out bar 26. Then, the OLED 12 can be wound up into the cylinder 14 by the winding action of the constant force spring 20. Free stop is possible also during winding.

In the electrical operation of the display device 10A, the motor 22 is rotated forward or backward. In this operation, the motor 22 rotates the rotating shaft 50, the friction disc 58, and the inner ring 60b. The rotation of the friction disc 58 is transmitted to the outer ring 60a via the friction plates 58b and 60c. The outer ring 60a is integral with the cylinder 14, meaning that the OLED 12 can be unwound and wound while the cylinder 14 being rotated. The other end 12b of the OLED 12 is provided with the pull-out bar 26 that doubles as a weight. The unwinding force Fd of the pull-out bar 26 is offset by the constant force spring 20, and the motor 22 is capable of unwinding and winding the OLED 12 with a sufficiently small output. Also in the case of the electrically operations, the OLED 12 is stoppable at any position.

The power to drive the cylinder 14 by the motor 22 is small enough, so the friction force between the friction plates 58b and 60c is also small enough to minimize deterioration of the friction plates 58b and 60c. If the frictional force is reduced due to wear of the friction plates 58b and 60c, the adjustment nut 54 is adjustable again to restore the frictional force to an appropriate level.

The power required to rotate the cylinder 14 by the motor 22 is sufficiently small, so the frictional force of the friction plates 58b and 60c which transmit the power is sufficiently small compared with the forces Fu and Fd of 800 gf. It has been confirmed that approximately 100 to 200 gf is sufficient, as described above. Considering the forces Fu and Fd as the standard, then about ⅛ to ¼ is sufficient.

As described above, the OLED 12 of the display device 10A can be unwound and wound electrically or manually. The display device 10A, including the constant force spring 20 on the opposite side of the motor 22 and the drag mechanism 24A, gives a good weight balance. After removing the covers 18a, 18b, the drag mechanism 24A is exposed from the X1 end, and the motor 22 and the drag mechanism 24A are exposed from the X2 end, thus making maintenance easy.

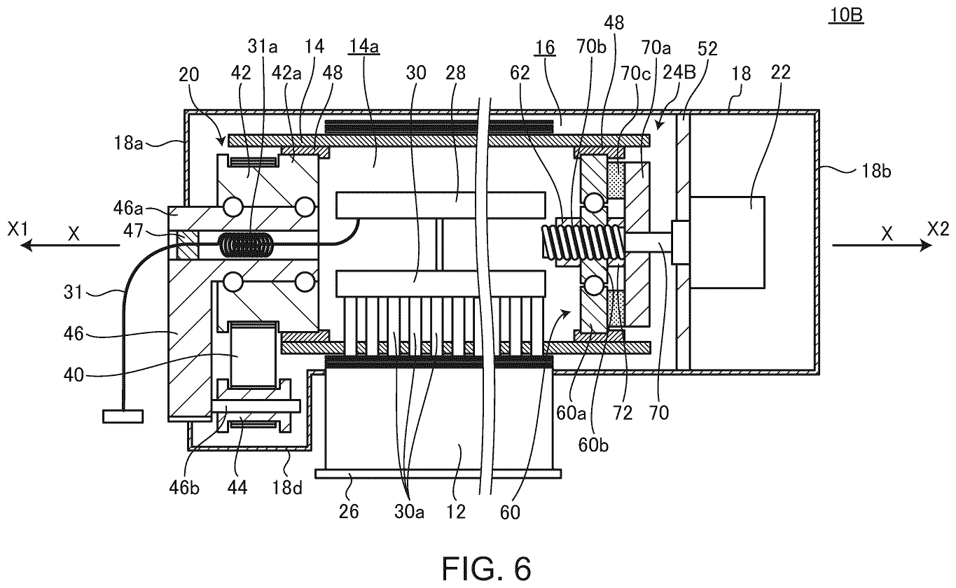

FIG. 6 is a schematic cross-sectional front view of the display device 10B according to one or more embodiments. The display device 10B includes a drag mechanism 24B in place of the drag mechanism 24A. For the drag mechanism 24B, like numbers indicate like components in the drag mechanism 24A, and their detailed descriptions are omitted.

The drag mechanism 24B includes a rotating shaft 70, a friction disc 70a, and an annular spacer 72. The rotating shaft 70 and the friction disc 70a correspond to the rotating shaft 50 and the friction disc 58 described above. The friction disc 70a is integral with the rotating shaft 70. The friction disc 70a has an X1 side face, on which a friction plate 70c is placed. The friction plate 70c is the same as the friction plate 58b described above. The annular spacer 72 is placed between the friction disc 70a and the inner ring 60b. The rotating shaft 70 has a tip threaded portion 70b that protrudes from the center hole of the inner ring 60b toward the X1 end. The inner ring 60b is held in place by the annular spacer 72 and the fixing nut 62, which is screwed onto the tip threaded portion 70b. The inner ring 60b and the tip threaded portion 70b may be configured to be non-rotatable to each other by a D-cut surface, for example. The drag mechanism 24B has a simpler structure than the drag mechanism 24A.

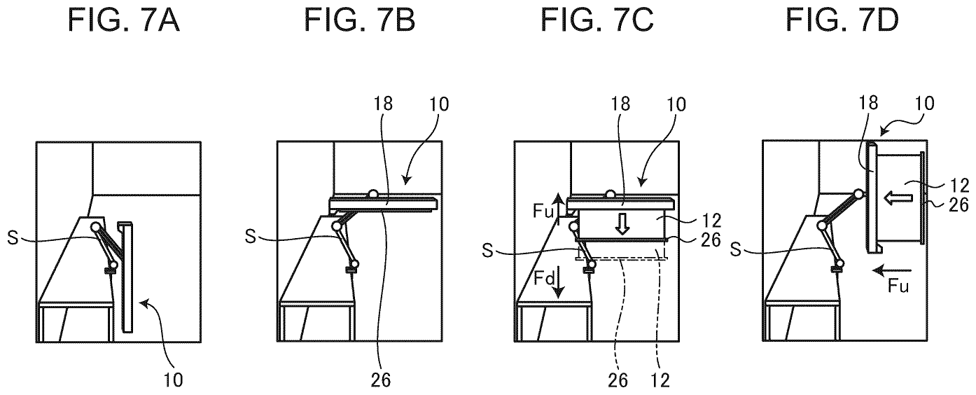

FIGS. 7A-7D illustrate examples of the use of the display device, with FIG. 7A illustrating the storage state, FIG. 7B illustrating the ready for use state, FIG. 7C illustrating the use state, and FIG. 7D illustrating another use state.

The display device 10 is small and lightweight, so it is attachable to a lighting desk stand S as illustrated in FIGS. 7A-7D and movable to any desired position for use. As illustrated in FIG. 7A, the display device 10 may be stored vertically so as to reduce the space it occupies.

As illustrated in FIG. 7B, when in use, the display device 10 may be set horizontally at any position and height. From this state, the OLED 12 may be pulled out downward and used as illustrated in FIG. 7C. Any pulling amount of the OLED 12 may be set, as described above.

As illustrated in FIG. 7D, when the display device 10 is housed, it may be directed vertically. Then, the unwinding force Fd acting downward by the pull-out bar 26 on the OLED 12 disappears. Then, only the winding force Fu by the constant force spring 20 acts on the OLED 12, making it possible to automatically wind the OLED 12 without using power. Of course, winding may be performed manually or electrically at the previous stage. The display device 10 may be stored horizontally. The display device 10 is small and lightweight, so it can be used as a wall-mounted type or a magnetically attached type.

The present invention is not limited to the above-described embodiments, and can be modified freely without deviating from the scope of the present invention.

### DESCRIPTION OF SYMBOLS

10, 10A, 10B display device
12 OLED
12a one end
12b the other end
14 cylinder (winder)
14b slit
16 space
18 cover
18c slit
20 constant force spring
22 motor
24A, 24B drag mechanism
26 pull-out bar (weight)
28 controller
30 display controller
40 elastic band
42 first pulley
44 second pulley
46 spring support
50 rotating shaft
50a base threaded portion
50b tip threaded portion
50c intermediate portion
54 adjustment nut
56 coil spring
58 friction disc
58b, 60c friction plate
60a outer ring
60b inner ring
62 fixing nut
70c friction plate
72 annular spacer

What is claimed is:

1. A display device comprising: an OLED;
a winder that winds the OLED from one end of the OLED;
a cover that keeps a winding space for the OLED between the winder and the cover;
a constant force spring that applies a winding force of the OLED to the winder;
a motor configured to give at least one of winding and unwinding forces of the OLED to the winder;
a drag mechanism configured to transmit rotation between the motor and the winder via a friction element; and
a weight at the other end of the OLED to apply a pull-out force that counterbalances the winding force by the constant force spring.

2. The display device according to claim 1, wherein
the winder is tubular, inside of which a display controller of the OLED is disposed along a direction of an axis of the tubular winder.

3. The display device according to claim 1, wherein
the friction element is placed to be non-rotatable relative to a rotating shaft of the motor but movable in an axial direction of the motor, and is elastically pressed against a friction target by a spring receiving a biasing force from a screw and a nut.

4. The display device according to claim 1, wherein
the constant force spring includes:
an elastic band that is spiral inherently;
a first pulley at one end of the winder, the elastic band being wound around the first pulley in a direction opposite to the inherent spiral direction of the elastic band; and
a second pulley that winds the elastic band that is unwound from the first pulley in the inherent spiral direction of the elastic band.

5. The display device according to claim 1, wherein
the motor and the drag mechanism, and the constant force spring are disposed on the opposite sides of the winder.
